(19) United States
(12) Patent Application Publication
(10) Pub. No.: US 2009/0001479 A1
(43) Pub. Date: Jan. 1, 2009

(54) TRANSISTOR HAVING REDUCED GATE RESISTANCE AND ENHANCED STRESS TRANSFER EFFICIENCY AND METHOD OF FORMING THE SAME

(76) Inventors: Maciej Wiatr, Dresden (DE); Roman Boschke, Dresden (DE); Peter Javorka, Dresden (DE)

Correspondence Address: J. Mike Amerson;Williams, Morgan & Amerson, P.C., Suite 1100, 10333 Richmond, Houston, TX, 77042, US

(21) Appl. No.: 12/026,827

(22) Filed: Feb. 6, 2008

(30) Foreign Application Priority Data
Jun. 29, 2007 (DE) 10 2007 030 054.0

(51) Int. Cl. H01L 27/088; H01L 21/8234

(52) U.S. Cl. 257/384; 438/682; 257/E27.06; 257/E21.626

(57) ABSTRACT

By removing an upper portion of a complex spacer structure, such as a triple spacer structure, an upper surface of an intermediate spacer element may be exposed, thereby enabling the removal of the outermost spacer and a material reduction of the intermediate spacer in a well-controllable common etch process. Consequently, sidewall portions of the gate electrode may be efficiently exposed for a subsequent silicidation process, while the residual reduced spacer provides sufficient process margins. Thereafter, highly stressed material may be deposited, thereby providing an enhanced stress transfer mechanism.

### BACKGROUND OF THE INVENTION

1. Field of the Invention

Generally, the subject matter disclosed herein relates to the formation of integrated circuits, and, more particularly, to the formation of transistors having strained channel regions caused by stressed overlayers, wherein material of spacer elements is partially removed after defining drain and source regions to enhance performance of highly scaled field effect transistors.

2. Description of the Related Art

During the fabrication of integrated circuits, a large number of circuit elements, such as field effect transistors, are formed on a given chip area according to a specified circuit layout. Generally, a plurality of process technologies are currently practiced, wherein, for complex circuitry, such as microprocessors, storage chips and the like, CMOS technology is currently the most promising approach due to the superior characteristics in view of operating speed and/or power consumption and/or cost efficiency. During the fabrication of complex integrated circuits using CMOS technology, millions of complementary transistors, i.e., N-channel transistors and P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely doped channel region disposed between the drain region and the source region.

The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on the dopant concentration, the mobility of the majority charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region is one important factor that determines performance of the MOS transistors. Thus, the reduction of the channel length, and associated therewith the reduction of the channel resistivity, is a dominant design criterion for accomplishing an increase in the operating speed of the integrated circuits. Another important aspect regarding the performance of highly scaled transistors is the conductivity of the gate electrode which is frequently provided in the form of a polysilicon line, the electrical conductivity of which may usually be enhanced by forming a metal silicide in the polysilicon material.

The reduction of the transistor dimensions, however, entails a plurality of issues associated therewith that have to be addressed so as to not unduly offset the advantages obtained by steadily decreasing the channel length of MOS transistors. One major problem in this respect is the development of enhanced photolithography and etch strategies to reliably and reproducibly create circuit elements of critical dimensions, such as the gate electrode of the transistors, for every new device generation. Moreover, highly sophisticated dopant profiles, in the vertical direction as well as in the lateral direction, are required in the drain and source regions to provide low sheet and contact resistivity in combination with a desired channel controllability. In addition, the vertical location of the PN junctions with respect to the gate insulation layer also represents a critical design criterion in view of leakage current control. Hence, reducing the channel length also requires reducing the depth of portions of the drain and source regions with respect to the interface formed by the gate insulation layer and the channel region, thereby requiring sophisticated implantation techniques.

Irrespective of the technological approach used, sophisticated spacer techniques are necessary to create the highly complex dopant profile and to serve as a mask in forming metal silicide regions in the gate electrode and the drain and source regions in a self-aligned fashion. Since the continuous size reduction of the critical dimensions, i.e., the gate length of the transistors, necessitates the adaptation and possibly the new development of process techniques concerning the above-identified process steps, it has been proposed to enhance device performance of the transistor elements by increasing the charge carrier mobility in the channel region for a given channel length. In principle, at least two mechanisms may be used, in combination or separately, to increase the mobility of the charge carriers in the channel region. First, the dopant concentration within the channel region may be reduced, thereby reducing scattering events for the charge carriers and thus increasing the conductivity. However, reducing the dopant concentration in the channel region significantly affects the threshold voltage of the transistor device, thereby making a reduction of the dopant concentration a less attractive approach unless other mechanisms are available to adjust a desired threshold voltage. Second, the lattice structure in the channel region may be modified, for instance by creating tensile or compressive strain, which results in a modified mobility for electrons and holes. For example, creating tensile strain in the channel region formed in a silicon region having a standard crystallographic orientation, i.e., the surface is a (100) equivalent plane and the channel length is oriented along a <110> equivalent axis, increases the mobility of electrons, which in turn directly translates into a corresponding increase in the conductivity and thus transistor performance. On the other hand, compressive stress in the channel region may increase the mobility of holes, thereby providing the potential for enhancing the performance of P-type transistors. Consequently, it has been proposed to introduce, for instance, a silicon/germanium layer or a silicon/carbon layer in or below the channel region to create tensile or compressive stress. Although the transistor performance may be considerably enhanced by the introduction of stress-creating layers in or below the channel region, significant efforts have to be made to implement the sequence for forming corresponding stress layers into the conventional and well-approved CMOS technique. For instance, additional epitaxial growth techniques have to be developed and implemented into the process flow to form the germanium- or carbon-containing stress layers at appropriate locations in or below the channel region. Hence, process complexity is significantly increased, thereby also increasing production costs and the potential for a reduction in production yield.

Another promising approach is the creation of stress in the insulating layer, which is formed after finishing the transistor elements to embed and “passivate” the transistors and which receives metal contacts to provide the electrical connection to the drain/source regions and the gate electrode of the transistors. Typically, this insulation layer comprises at least one etch stop layer or liner and a further dielectric layer that may be selectively etched with respect to the etch stop layer or liner. In the following, the dielectric layer may be referred to as an interlayer dielectric material and the etch stop layer may be referred to as a contact etch stop layer. In order to obtain an efficient stress transfer mechanism to the channel region of the transistor for creating strain therein, the contact etch stop layer, that is located in the vicinity of the channel region, has to be positioned closely to the channel region. However, due to the complex dopant profiles that are usually required in highly advanced transistors, an advanced spacer structure is typically provided including three or more individual spacer elements used as implantation masks in respective implantation steps for appropriately positioning the dopants in the drain and source region on the basis of suitable implantation parameters. A technique using three individual spacer elements for defining the dopant profile in the drain and source regions will hereinafter also be referred to as a triple spacer approach.

In highly scaled transistor architectures, the performance gain obtained by strain-inducing sources and the reduction of the over transistor dimensions may, however, be less than desired due to several problems associated with further device scaling, as will be described with reference to FIGS. 1a-1b in more detail.

FIG. 1a schematically illustrates a semiconductor device 100 comprising a first transistor 150A and a second transistor 150B, which may represent transistors of different conductivity type, or any other neighboring transistors defining a distance 150D therebetween that may be approximately a few hundred nanometers and significantly less, such as 100 nm and less, for highly scaled semiconductor devices. The transistors 150A, 150B are formed above a substrate 101, such as a bulk silicon substrate or a silicon-on-insulator (SOI) substrate, depending on the overall device configuration. Furthermore, a silicon-based semiconductor layer 102 is formed above the substrate 101 and may comprise isolation structures (not shown) used to define active regions, i.e., regions receiving appropriate dopant concentrations for patterning the conductivity of the base silicon material in a required manner. As shown, the silicon-based layer 102 may comprise drain and source regions 151A, 151B having a complex lateral and vertical concentration profile in order to enhance controllability of a corresponding channel region 152, maintain a low overall serious resistance, reduce leakage currents and the like. Depending on the conductivity type of the transistors 150A, 150B, the drain and source regions 151A, 151B may be formed on the basis of P-type dopants and N-type dopants, respectively. The transistors 150A, 150B further comprise a gate electrode 153, which, in the manufacturing stage shown, is typically comprised of polysilicon and which is formed on a gate insulation layer 154 isolating the gate electrode 153 from a channel region 152. The gate insulation layer 154 may be formed on the basis of silicon dioxide, silicon nitride, silicon oxynitride and the like, wherein a thickness of the gate insulation layer 154 for silicon dioxide based materials has reached 2 nm and less, which is near the physical boundaries for the thickness of gate dielectric based on silicon dioxide with respect to static leakage currents. Hence, other mechanisms may be required for enhanced channel control, such as increasing the charge carry mobility in the channel region 152, unless appropriate dielectric materials having a moderately high permittivity prove to be reliable candidates for replacing silicon dioxide based materials. The gate electrodes 153 have formed on sidewalls thereof a spacer structure 155 that is provided in the example shown as a triple spacer structure comprising an offset spacer 155A comprised of silicon dioxide, a first spacer element 155B and a second spacer element 155C, which are typically made of silicon nitride. Furthermore, the spacer structure 155 comprises a liner material, such as a silicon dioxide liner 155D, separating the first and second spacer elements 155B, 155C. Similarly, a liner 155E may be formed between the offset spacer 155A and the first spacer 155B.

The semiconductor device 100 may be formed on the basis of well-established process techniques, including the definition of isolation structures (not shown) followed by appropriate implantation techniques for defining a desired vertical dopant distribution within and below the channel regions 152. Thereafter, the gate insulation layer 154, in combination with the gate electrode 143, may be formed on the basis of sophisticated oxidation and/or deposition processes, when a silicon dioxide based material is considered for the layer 154, followed by the deposition of an appropriate gate electrode material, such as polysilicon. Next, the gate electrode material and the gate insulation layer may be patterned on the basis of advanced lithography and etch processes so that a length of the gate electrode 153 may be obtained in the range of 50 nm and less, wherein the distance between neighboring gate electrodes 153 may also be adjusted to approximately 200 nm and even less in densely packed device areas, as previously explained. Next, a portion of the spacer structure 155, i.e., the offset spacer 155A may be formed with an appropriate spacer width so as to act, in combination with the gate electrode 153, as an implantation mask for defining a portion of the drain and source regions 151A, 151B. The offset spacer 155A may be formed by depositing a silicon dioxide material in a highly conformal manner and subsequently performing a selective plasma based etch process using well-established etch chemistries, wherein the etch process parameters are adjusted to obtain a high degree of anisotropy.

Thereafter, respective implantation processes may be performed, for instance, for amorphizing the silicon-based layer 102 down to a specified depth, incorporating the specific type of dopant species for defining a shallow portion of the drain and source regions 151A, 151B and for increasing the concentration of dopants of opposite conductivity type with respect to the drain and source regions 151A, 151B in order to make the corresponding dopant gradients steeper for defining moderately sharp PN junctions. Next, the liner material 155E may be formed by depositing a silicon dioxide layer followed by the deposition of a silicon nitride material with a specified thickness, followed by a highly anisotropic etch process using an etch chemistry that has a high etch selectivity between the liner material and the spacer material. After the anisotropic etch process, the first space elements 155B are obtained and may then be used as an efficient implantation mask for performing another implantation process for incorporating dopant species with appropriately selected implantation parameters, such as energy and dose, in order to obtain the desired penetration depth and concentration. Thereafter, the sequence may be repeated to obtain the second spacer elements 155C to establish the final dopant concentration of the drain and source regions 151A, 151B. Intermittently, or after the entire implantation process is completed, appropriate anneal processes may be performed to re-crystallize the material in the drain and source regions 151A, 151B and to activate the implanted dopant atoms. As previously explained, by using the triple spacer structure 155, the drain and source regions 151A, 151B may be shaped in the vertical and lateral directions to obtain a desired high performance of the transistors 150A, 150B. As previously discussed, additional performance gain may be obtained by inducing a certain type of strain in the channel regions 152, for instance, by providing a highly stressed material above the transistors 150A, 150B, wherein the magnitude of strain may depend on the amount and intrinsic stress level of the respective material.

FIG. 1b schematically illustrates the semiconductor device 100 with a first stressed dielectric layer 103A, which may represent a contact etch stop layer above the first transistor 150A, while a second contact etch stop layer 103AB with a high intrinsic stress level may be formed above the second transistor 150B. In the example shown, the layer 103A has a high compressive stress to induce a respective compressive strain in the channel region 152 of the transistor 150A. Similarly, the transistor 150B may receive a tensile strain caused by a high intrinsic tensile stress of the layer 103AB. Moreover, the transistors 150A, 150B comprise metal silicide regions 105 formed on the drain and source regions 151A, 151B and metal silicide regions 104 formed on the gate electrode 153. Typically, the metal silicide regions 104, 105 may be formed in a common process sequence, for instance, on the basis of cobalt, nickel and the like, by depositing a metal layer and initiating a chemical reaction during which the spacer structure 155 exhibits a substantially inert behavior so that non-reacted metal may be readily removed from the spacer structure 155, thereby substantially avoiding the creation of undesired conductive paths between the metal silicide regions 104 and 105. Thereafter, the etch stop layers 103A, 103B may be formed on the basis of well-established deposition and patterning regimes, for instance, using silicon nitride material which may be efficiently deposited by plasma enhanced chemical vapor deposition (PECVD) with a desired high intrinsic stress level. Thereafter, an interlayer dielectric material may be deposited, such as silicon dioxide, which may then be patterned to receive respective contact openings, which may extend down to the metal silicide regions 105.

Thus, for reduced distances 150D, the amount of stressed material of the layers 103A, 103AB may be restricted due to the limitations of the gap fill capabilities of the respective patterning sequence for forming the stress layers 103A, 103AB. Moreover, the stress transfer mechanism provided by the layers 103A, 103AB may be reduced by the subsequent formation of contact openings, since the respective openings may remove a significant portion of the stressed dielectric material in densely packed device areas. Thus, for highly scaled semiconductor devices, the efficiency of the stress transfer mechanism may be significantly reduced. Furthermore, as previously explained, an important factor for the overall transistor performance is the gate series resistance, which strongly depends on the conductivity and the thickness of the metal silicide region 104. Thus, for a reduced channel length, the overall amount of metal silicide in the region 104 may also be reduced, thereby increasing the series resistance of the gate electrode 153, which may translate into increased switching times and thus reduced transistor performance for sophisticated logic devices.

In view of this situation, it has been proposed to remove a portion of the spacer structure 155 prior to performing the silicidation process, thereby at least increasing the amount of metal silicide in the regions 105 and also providing the possibility of positioning an increased amount of highly stressed material in the vicinity of the channel regions 152 so that the formation of the contact openings may have a less pronounced effect on the overall stress transfer mechanism. However, the devices may nevertheless suffer from an increased series resistance of the gate electrode. In other approaches, a reduced spacer structure 155, for instance by omitting the second spacer element 155C to reduce the overall process complexity, is proposed, but this strategy may not seem a desirable approach for advanced applications, since the dopant profiling obtained by the triple spacer structure 155 may result in enhanced transistor performance compared to a dopant profile obtained on the basis of a less complex spacer structure.

The present disclosure is directed to various methods and device that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein relates to semiconductor devices and methods for forming the same, in which a complex spacer structure may be used during the definition of drain and source regions, wherein, prior to the formation of metal silicide regions, a significant portion of the spacer structure may be removed in a highly controllable manner, thereby also exposing portions of the sidewall of the gate electrode, which are then available for the silicidation process. Due to the superior controllability of the respective material removal process, a high degree of process uniformity may be obtained while also a well-defined portion of the spacer structure may be maintained in order to act as a silicidation mask for avoiding any shorts between the gate electrode and the drain and source regions. On the other hand, a significantly reduced gate series resistance may be achieved by increasing the surface portion of the gate electrode in a highly controllable manner for forming therein metal silicide. During the controllable removal of a significant portion of the spacer structure, an outermost spacer element may be substantially completely removed, while an inner spacer element may be reduced in a controllable manner due to a significantly lower etch rate, so that the size of the final reduced spacer structure may be controlled by adjusting the etch time.

One illustrative method disclosed herein comprises forming a transistor element comprising a gate electrode structure having formed on a sidewall thereof a spacer structure including at least a first spacer element and a second spacer element that are comprised of substantially the same material, wherein the first spacer element is formed laterally between the gate electrode structure and the second spacer element and wherein the spacer structure comprises a liner material separating the first and the second spacer elements. The method further comprises removing an upper portion of the first and the second spacer elements and the liner material in a common removal process to expose a top portion of the first spacer element. Furthermore, the second spacer element and material of the first spacer element is removed in a selective etch process to form a reduced first spacer element. Finally, metal silicide regions are formed in the gate electrode structure and the drain and source regions of the transistor on the basis of the reduced first spacer element.

Another illustrative method disclosed herein comprises forming a first spacer element laterally adjacent to a gate electrode of a transistor. A liner material is formed on the first spacer element and a second spacer element is formed on the liner material. Furthermore, the method comprises forming a sacrificial material layer above the gate electrode and the first and second spacer elements and removing the sacrificial material layer by performing a first etch process to expose the second spacer element and a portion of the first spacer element. Additionally, the method comprises removing the second spacer element and a part of the first spacer element in a common second etch process.

An illustrative semiconductor device disclosed herein comprises a first transistor comprising a gate electrode and a spacer element formed laterally adjacent to the gate electrode to expose a portion of the sidewalls of the gate electrode. The first transistor further comprises drain and source regions and a channel region formed in a semiconductor material. Furthermore, metal silicide is formed in the drain and source regions and a top surface and the exposed sidewall portion of the gate electrode. Furthermore, the semiconductor device comprises a first etch stop layer having an intrinsic stress level designed to induce a first type of strain in the channel region for enhancing charge carrier mobility therein. Additionally, an interlayer dielectric material is formed above the first etch stop layer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a semiconductor device including closely spaced transistor elements formed on the basis of a triple spacer technique and a stressed contact etch stop layer during various manufacturing stages according to conventional manufacturing techniques;

FIGS. 2a-2g schematically illustrate cross-sectional views of a semiconductor device comprising transistor elements in densely packed device areas during various manufacturing stages, in which sophisticated dopant profiles are formed on the basis of a plurality of spacer elements, the size of which is then significantly reduced in a highly controllable manner, according to illustrative embodiments; and

FIGS. 3a-3b schematically illustrate cross-sectional views of transistor elements formed on the basis of a triple spacer technique, wherein an upper portion of the spacer structure is removed in a controllable manner to allow the removal of the outermost spacer element and the size reduction of an inner lying spacer element in a common etch process in a highly controllable manner according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein provides enhanced techniques and semiconductor devices in which highly sophisticated dopant profiles are formed on the basis of a spacer structure including a plurality of individual spacer elements, such as a triple spacer structure, thereby maintaining a high transistor performance, while an outermost spacer element may be removed, while an inner spacer element may also be reduced in size in a highly controllable manner on the basis of a common etch process, thereby enabling the deposition of an increased amount of highly stressed dielectric material. Consequently, by efficiently increasing the spacing between two densely packed transistor elements, after the definition of the complex dopant profile of the drain and source regions, respective contact openings may be formed therebetween, wherein an adverse effect on the stress transfer mechanism is greatly reduced. Furthermore, by removing a significant portion of an inner lying spacer element, sidewalls of the gate electrode may be efficiently exposed to a certain degree, determined by the residual size of the inner spacer element, thereby providing an increased surface area for a subsequent silicidation process, resulting in a reduced series resistance of the gate electrode. Removing the outermost spacer element, while controllably removing a portion of the inner spacer element, may be achieved by exposing an upper portion of the inner spacer element so that the etch ambient of a highly selective etch process may attack the exposed outermost spacer element while also providing a certain, yet significantly reduced, etch rate for the inner spacer element, due to the exposed upper portion. Consequently, the size of the inner space element may be reduced in a well-controllable manner, due to the reduced etch rate, thereby also enabling the adjustment of the degree of exposure of sidewall portions of the gate electrode in a subsequent etch or cleaning process prior to performing the silicidation process. In some illustrative aspects, the controlled exposure of an upper portion of the inner spacer element may be accomplished on the basis of a sacrificial material layer, which may, after deposition, be removed in one illustrative embodiment by a plasma assisted etch process, thereby providing highly uniform process conditions. In other cases, the sacrificial material may be removed, alternatively or additionally, by a polishing process, in which an upper portion of the spacer structure may also be removed.

The embodiments disclosed herein are thus highly advantageous in the context of highly scaled semiconductor devices comprising advanced transistor elements having a gate length of approximately 50 nm and less, in which transistor performance is enhanced by providing a highly stressed dielectric material above the transistor element. Hence, in this case, a sophisticated dopant profile may be provided in combination with an efficient stress transfer mechanism along with a reduced resistance in the gate electrode and also in the conductive path formed by the drain and source regions and the channel region. Furthermore, in device areas having a high integration density, the distance between neighboring circuit elements, which is determined in the final phase of the manufacturing stage by the width of the respective spacer structure, may be efficiently reduced, thereby also enhancing the manufacturing of respective contact openings, since the metal silicide area on which contact openings should “land” is increased, while the amount of stressed dielectric material surrounding the contact metal is also increased, thereby reducing the negative effect of the contacts with respect to stress relaxation, since the ratio between stressed dielectric material and stress relaxing metal is increased. It should be appreciated, however, that the principles disclosed herein are also advantageously applicable to any transistor configuration, such as sophisticated SOI transistors, bulk transistors, transistors including other strain-inducing mechanisms, such as transistors comprising strained or relaxed semiconductor alloys in a silicon-based active region and the like. Thus, the embodiments disclosed herein should not be considered as being restricted to any specific transistor configuration unless specifically pointed out in the specification and/or the appended claims.

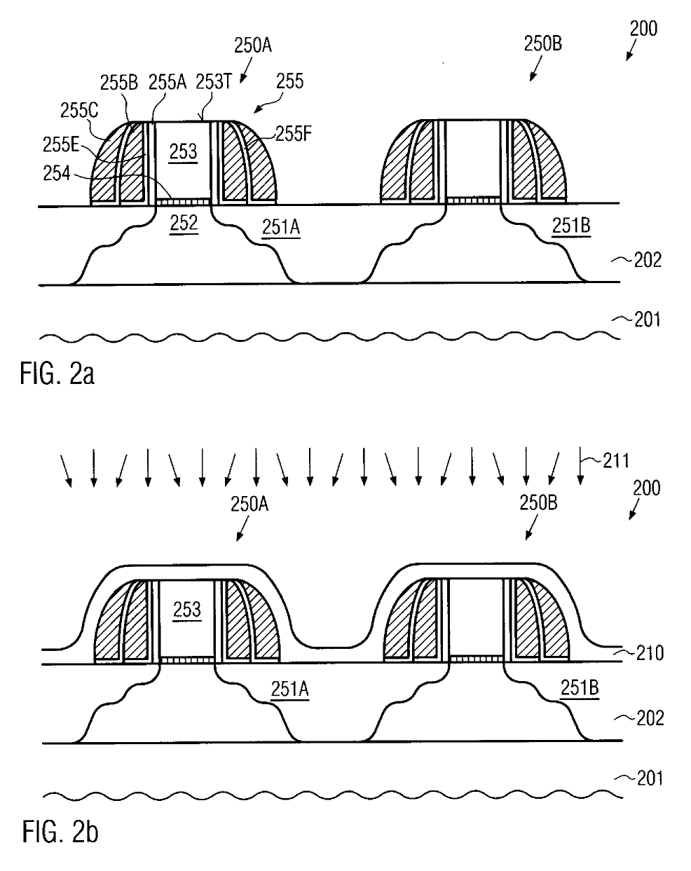

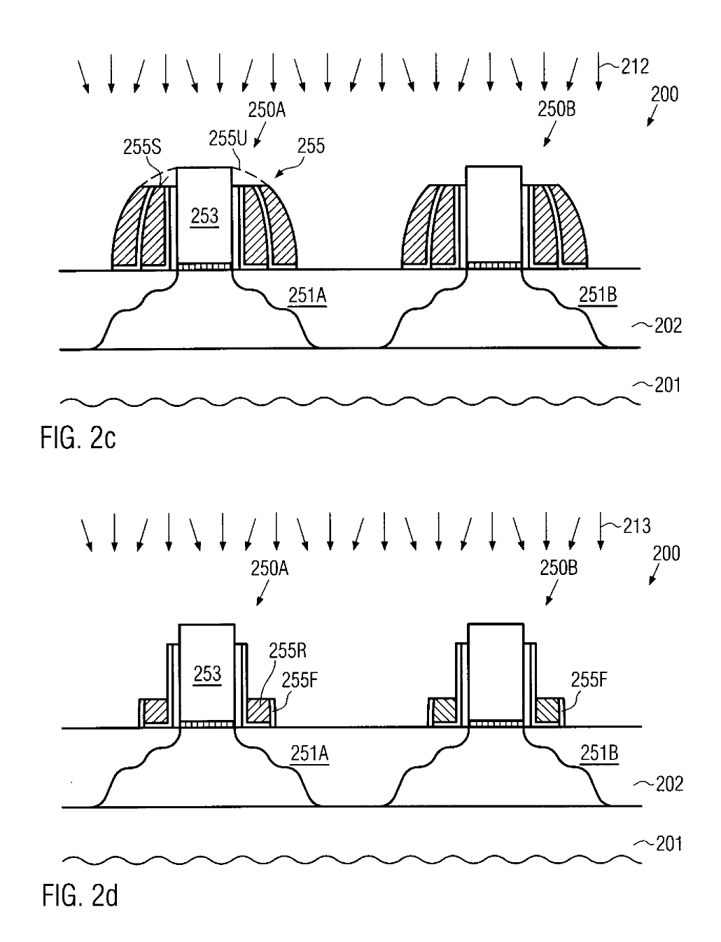

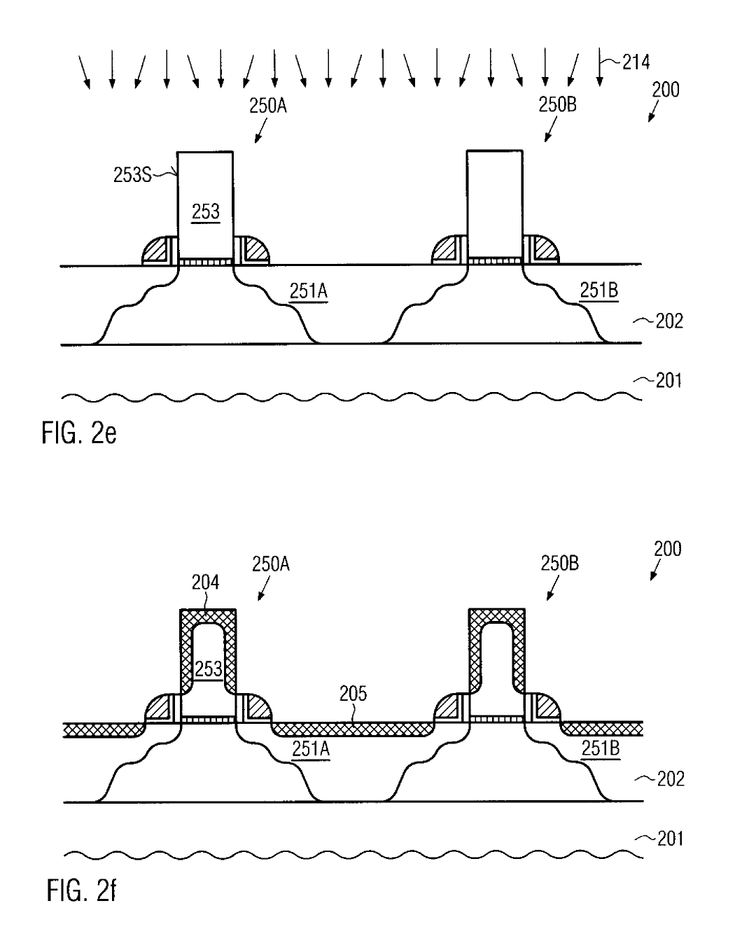

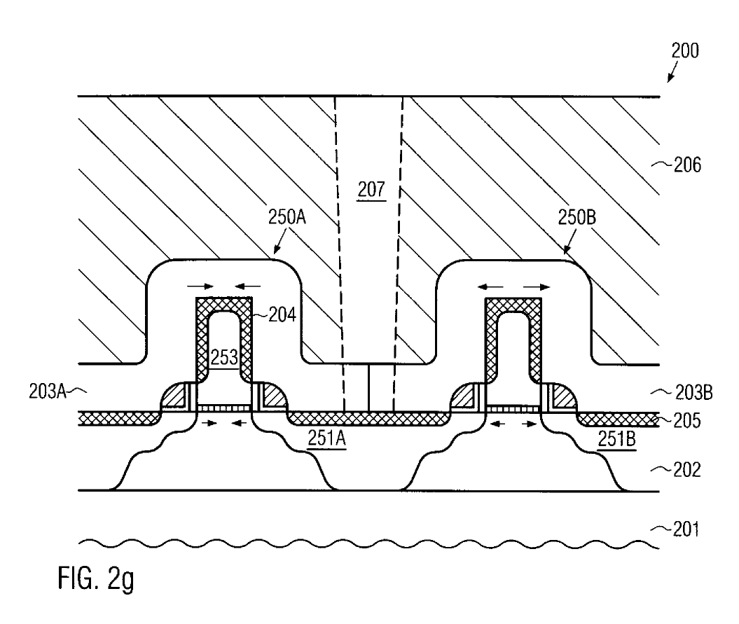

FIG. 2a schematically illustrates a semiconductor device 200, which may comprise one or more transistor elements 250A, 250B. The transistors 250A, 250B may represent transistors of different conductivity type, such as a P-channel transistor and an N-channel transistor, or may represent similar transistors formed in a specific device region, which may include individual transistors with increased spacing therebetween, while, in other cases, the transistors 250A, 250B may represent closely spaced transistor elements. The semiconductor device 200 may comprise a substrate 201, such as a bulk semiconductor substrate, having formed thereabove an appropriate semiconductor layer 202, which may be comprised of a silicon-based material, while other components, such as germanium, carbon, tin or any appropriate dopant species, may also be present. The semiconductor layer 202, in combination with the substrate 201, may, at least locally, form a bulk configuration, i.e., the semiconductor layer 202 may not be isolated in the vertical direction, while, in other cases, at least locally, the layer 202 and the substrate 201 may represent an SOI configuration, in which a buried insulation layer (not shown) may provide an isolation in the vertical direction. In the lateral direction, respective isolation structures, such as trench isolations (not shown), may define certain active areas. The transistors 250A, 250B may have respective drain and source regions 251A, 251B, which may differ in their conductivity type, the type of dopants used for defining the drain and source regions 251A, 251B, and the like. Furthermore, the transistors 250A, 250B may comprise gate electrodes 253 formed on gate insulation layers 254 that separate the gate electrodes 253 from a channel region 252. Furthermore, a spacer structure 255 is provided on the sidewalls of the gate electrodes 253. The spacer structure 255 may comprise a plurality of individual spacer elements 255A, 255B and 255C and liner materials 255E, 255F, which, in the embodiment shown, represent a triple spacer structure. In one illustrative embodiment, the spacers 255B, 255C, also indicated as first and second spacers, may be comprised of substantially the same material, while the inner most offset spacer 255A may be formed from a different material. It should be appreciated that the spacer structure 255 may comprise even more of the spacer elements than 255A, 255B and 255C, if more sophisticated profiles for the drain and source regions 251A, 251B are required.

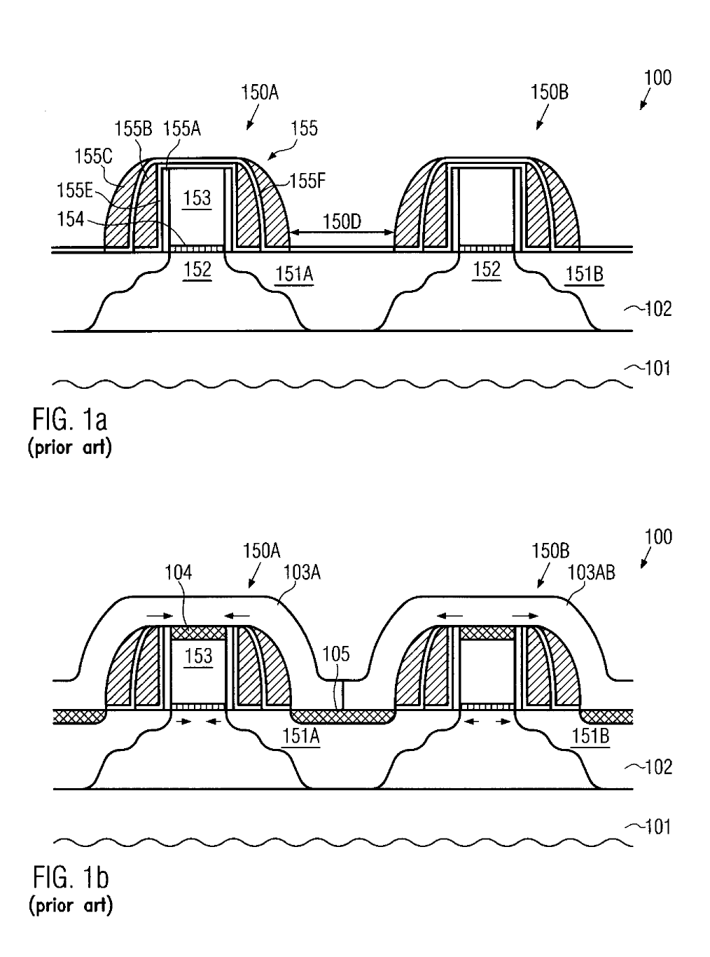

The semiconductor device 200 as shown in FIG. 2a may be formed on the basis of similar process techniques as previously described with reference to the device 100. Hence, a respective description of these processes will be omitted here. It should be appreciated that, if a more complex spacer structure 255 may be required, a corresponding process sequence including the deposition of an appropriate liner material, such as the liners 255E and 255F, may be performed, followed by the deposition of an appropriate spacer material, which may then be patterned on the basis of an anisotropic etch process as previously described. Furthermore, in one embodiment, the first and the second spacer elements 255B and 255C may be comprised of silicon nitride, while the liner materials 255F, 255E may be made on the basis of silicon dioxide and also the offset spacer 255A may be comprised of silicon dioxide, as previously explained with reference to the device 100 and the spacer structure 155. In other illustrative embodiments, the first and the second spacer elements 255B, 255C may be comprised of different material compositions as long as a material removal during a common etch process may be achieved. In still other illustrative embodiments, the first and second spacers 255B, 255C may be comprised of a material having a similar etch behavior, such as silicon dioxide or similar materials, while the liner materials 255F, 255E may be comprised of any appropriate material exhibiting high etch selectivity with respect to the spacers 255B, 255C. In this case, for instance, the liners 255F, 255E may be comprised of silicon nitride, while the spacers 255B, 255C may be comprised of silicon dioxide. Similarly, the offset spacer 255A may be formed of any appropriate material, which, in some illustrative embodiments, may exhibit a similar etch behavior compared to the liner materials 255F, 255E. It should further be appreciated that, in the manufacturing stage shown, a top surface 253F of the gate electrode 253 may be exposed, as well as portions of the drain and source regions 251A, 251B that are not covered by their respective spacer structures 255. In other cases, as is for instance illustrated for the device 100 previously described with reference to FIG. 1a, the respective liner materials or any residuals thereof may still be present on the surface 253T and exposed portions of the semiconductor layer 202.

FIG. 2b schematically illustrates the semiconductor device 200 at a further advanced manufacturing stage, wherein a sacrificial layer 210 is formed above the transistors 250A, 250B on the basis of a deposition process 211, which, in one illustrative embodiment, is designed to provide the sacrificial layer 210 in a highly conformal manner with an appropriate thickness, which may range from approximately 5-20 nm. However, other thickness values may be used in other embodiments. For example, the deposition process 211 may be a chemical vapor deposition (CVD) process, such as thermal induced CVD process, a plasma enhanced CVD process and the like. The material composition of the sacrificial layer 210 may be selected in some embodiments such that a comparable etch rate is obtained during a subsequent etch process with respect to the liner materials 255E, 255F and the offset spacer 255A. For example, in one illustrative embodiment, the sacrificial layer 210 may comprise silicon dioxide, which may be formed on the basis of well-established deposition recipes. In other cases, the sacrificial layer 210 may be comprised of silicon oxynitride, silicon nitride and the like. In some cases, as explained before, it may be advantageous to provide the material of the layer 210 with substantially the same etch behavior as the liner materials 255E, 255F and the spacer 255A, when a subsequent etch ambient may have a high etch selectivity with respect to silicon and also to the material of the spacers 255B and 255C, since, in this case, enhanced process uniformity may be obtained during etching of an upper portion of the spacer structure 255. In other cases, when the respective etch process to be performed later on has high selectivity with respect to silicon material, while a selectivity between the materials of the spacers 255B, 255C on the one hand and the liners 255F, 255E and the spacer 255A is less pronounced, the sacrificial layer 210 may be provided in the form of any appropriate material having similar etch behavior as any of the materials of the spacer structure 255. In this case, the sacrificial layer 210 provides enhanced surface uniformity on the spacer structure 255, irrespective of any irregularities obtained during the prior processing, such as etch processes, implantation processes and the like.

FIG. 2c schematically illustrates the semiconductor device 200 during an etch process 212, which is designed to have a high selectivity with respect to the material of the gate electrode 253 and the drain and source regions 251A, 251B. In one illustrative embodiment, the etch process 212 may be designed as a plasma assisted etch process, wherein process parameters, such as bias power, amounts of polymer species and the like, may be adjusted to obtain a substantially isotropic etch behavior. For this purpose, well-established etch recipes may be used, as are available, for instance, for silicon dioxide, silicon oxynitride and the like, wherein the desired high selectivity with respect to silicon material may be achieved. Due to the provision of the sacrificial layer 210, the start conditions of the etch process 212 are highly uniform, since respective surface irregularities may be efficiently “equalized” during the preceding deposition process 211. During the etch process 212, increasingly material of the layer 210 may be efficiently removed, and, upon exposure of the spacer structure 255, the material of the offset spacer 255A and the liners 255F, 255E may be removed, thereby also removing to a certain degree material of the spacers 255B, 255C, even if the chemistry of the etch process 212 has a reduced etch rate with respect to the material of the spacers 255B, 255C. Thus, due to the highly uniform process conditions, an upper portion 255U of the initial spacer structure 255 may be removed in a well-controllable manner during the etch process 212, thereby exposing an upper portion or surface 255S of the spacer element 255B. Furthermore, the enhanced process uniformity provided by the sacrificial layer 210 also results in an enhanced process uniformity across the substrate 201, thereby exposing the respective upper portions or surfaces 255S of the transistor elements 250A, 250B in a uniform manner. Thus, the etch process 212 may be performed on the basis of an appropriate etch time so as to substantially completely remove the sacrificial layer 210 from surface portions of the spacer element 255C while, nevertheless, the size of the removed portion 255U may be adjusted with a high degree of uniformity across the entire substrate 201. In some cases, a respective cleaning process may be performed at a final phase of the etch process 212 or may be performed as a separate step to remove any residuals of the sacrificial layer 210 from exposed surface portions of the spacer 255C and also from the surface 255S.

In some illustrative embodiments, the etch process 212 may comprise a wet chemical etch step having a high selectivity with respect to the gate electrodes 253 and the drain and source regions 251A, 251B. For instance, hydrofluoric acid or other well-established wet chemical cleaning recipes may be used if the sacrificial layer 210 is subsequently comprised of silicon dioxide.

FIG. 2d schematically illustrates the semiconductor device 200 at a further advanced manufacturing stage. As shown, the device 200 is exposed to the ambient of a further etch process 213 designed to selectively remove material of the spacers 255B, 255C with respect to the material of the gate electrode 253, the semiconductor layer 202 and also with respect to the material of the liners 255F, 255E. For example, the etch process 213 may be a wet chemical etch process on the basis of hot phosphoric acid when the spacers 255B, 255C are comprised of a silicon nitride material. In other cases, the etch process 213 may be performed on the basis of hydrofluoric acid, if the spacers 255B, 255C are comprised of silicon dioxide, while the liners may be formed of a silicon nitride based material. Due to the substantially complete exposure of the outer spacer 255C, the material thereof may be efficiently removed during etch process 213, while also a certain degree of material removal may occur for the inner spacer 255B, which, however, due to the enclosure by the liner materials 255F and 255E may be attacked via the previously exposed surface 255S only, thereby obtaining in total a significantly lower removal rate compared to the material of the outer spacer 255C. Thus, during the process 213, the spacers 255B, 255C may commonly be etched, wherein, however, the outer spacer 255C may be substantially completely removed, while a significant portion of the inner spacer 255B may still be maintained. Due to the highly uniform exposure of the surface 255S, as previously explained, and due to the significantly reduced removal rate for the spacer 255B, the etch process 213 is well controllable so that the outer spacer 255C may be reliably removed and, thereafter, a controlled “over-etch time” may be applied to adjust the desired final height or size of the reduced inner spacer 255R. Appropriate process parameters, such as etch time for the process 213 in combination with the sequence for exposing the upper surface 255S, may be readily determined on the basis of respective test runs.

FIG. 2e schematically illustrates the semiconductor device 200 when exposed to a reactive ambient of a cleaning process 214 designed to remove residuals of the spacer structure 255 and form exposed portions of the semiconductor layer 202 for preparing the silicon-based materials of the gate electrode and of the drain and source regions 251A, 251B for receiving a metal silicide. The process 214 may be designed to selectively remove material of the offset spacer 255A in combination with residuals of the liners, thereby efficiently exposing a portion of the sidewall 253S of the gate electrode, wherein the degree of exposure may be substantially determined by the size of the reduced spacer 255R. The process 214 may be performed on the basis of well-established recipes, as may also be used in conventional techniques for preparing silicon-based surface areas for a subsequent silicidation process.

FIG. 2f schematically illustrates the semiconductor device 200 at a further advanced manufacturing stage. As shown, metal silicide regions 204 are formed in the gate electrodes 253 and metal silicide regions 205 are formed in the drain and source regions 251A, 251B. Due to the increased exposed surface areas of the silicon-based semiconductor materials, the metal silicide regions 205 may occupy an increased area and may therefore be positioned closer to the respective channel regions 252. Hence, a reduced serious resistance is obtained in the respective transistors 250A, 250B and also an increased “landing area” for respective contact openings may be obtained. Similarly, the metal silicide 204 in the gate electrode 253 may extend along the previously exposed sidewall portions 253S, thereby providing a significantly increased amount of metal silicide compared to conventional devices, such as the device 100 as shown in FIG. 1b, in which merely the top surface is covered by metal silicide. The metal silicides 204, 205 may be formed on the basis of well-established recipes, wherein the reduced spacer 255R provides sufficient process margins to avoid the creation of short circuits between the gate electrodes 253 and the corresponding drain and source regions 251A, 251B.

FIG. 2g schematically illustrates the semiconductor device 200 at a further advanced manufacturing stage, in which an interlayer dielectric material 206 is formed above the transistors 250A, 250B, wherein an etch stop material, in the embodiment shown provided in the form of a first etch stop layer 203A and second etch stop layer 230B, is located between the interlayer dielectric material 206 and the respective transistor devices 250A, 250B. Furthermore, as shown, the etch stop layers 203A, 203B, possibly in combination with portions of the interlayer dielectric material 206, may comprise a high intrinsic stress level designed to create a desired type of strain in the respective channel regions 252, as also previously explained. For instance, the transistor 250A may have formed thereabove the etch stop layer 203A and possibly further material layers of the material 206 exhibiting a high intrinsic stress level for generating a compressive strain in the channel region 252. For example, the first etch stop layer 203A may be provided in the form of silicon nitride material, a nitrogen-enriched silicon carbide material and the like, having a high compressive stress of approximately 2 Giga Pascal (GPa) and higher. Similarly, the second transistor 205E may comprise the second etch stop layer 203B with a high intrinsic tensile stress level, wherein further material layers may be provided having a tensile intrinsic stress. For instance, the second etch stop layer 203B may be provided in the form of silicon nitride having an intrinsic tensile stress of 1 Giga Pascal and higher.

The etch stop layers 203A, 203B and the interlayer dielectric material 206 may be formed on the basis of well-established process techniques, including sophisticated deposition and patterning regimes, wherein, due to the reduction of the initial spacer structure 255 to form the reduced spacer 255R, may significantly relax the constraints imposed on respective deposition techniques for forming the first and second stressed etch stop layers 203A, 203B. Hence, the layers 203A, 203B may possibly be provided with increased thickness while additionally the highly stressed material may be positioned more closely to the channel regions 252, thereby enhancing the overall stress transfer mechanism. After forming the interlayer dielectric material 206, a respective contact opening 207 may be formed on the basis of well-established techniques, which may have a less pronounced stress relaxing effect due to the reduced spacer 255R and thus increased amount of stressed material, as previously explained.

Consequently, enhanced dopant profiles for the drain and source regions 251A, 251B may be obtained on the basis of a multiple spacer structure, such as a triple spacer structure, while nevertheless increased gate conductivity, increased conductivity of the drain/source conductive path, in combination with an enhanced stress transfer mechanism, may be achieved.

In the embodiments described above, a substantially uniform process behavior with respect to reducing the initial spacer structure 255 is obtained for both transistor 250A, 250B. In other cases, it may be considered advantageous to individually control the height reduction of the respective spacer structures 255, which may be accomplished by providing an appropriately designed etch mask, for instance, during the etch process 213. In this case, a resist mask or any other appropriate mask material may be provided, for instance, during an initial phase of the etch process 213 above one of the transistors and may be removed after a certain etch time. During the remaining etch process, the outermost spacer element of the previously covered transistor may also be completely removed, while the reduction of size of the respective inner spacer may be less compared to the non-covered transistor element.

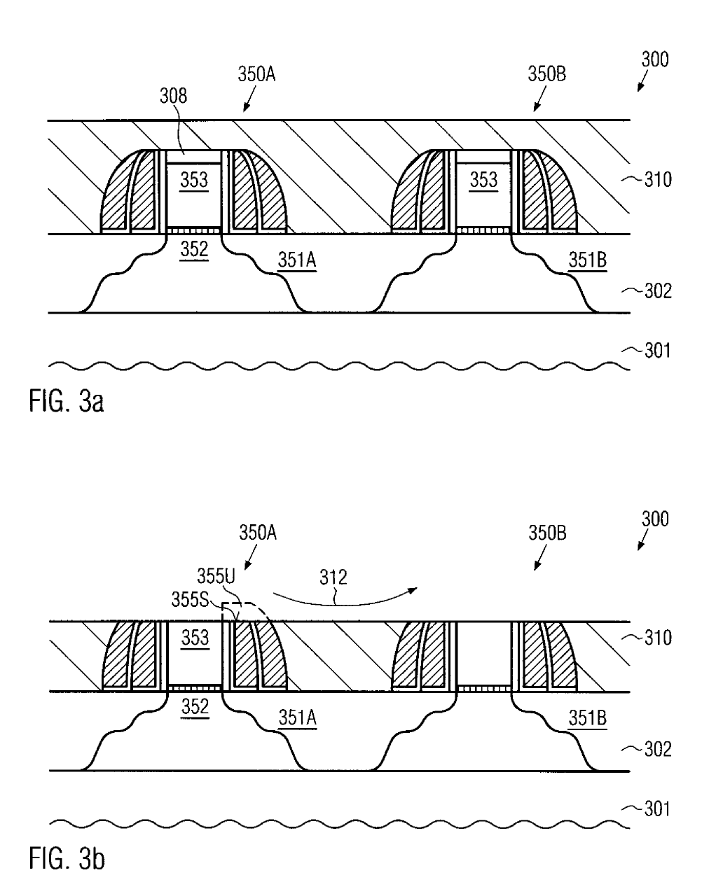

With reference to FIGS. 3a-3b, further illustrative embodiments will now be described, in which the exposure of the inner spacer element, i.e., the removal of an upper portion of the spacer structure, may be performed additionally or alternatively on the basis of a polishing process.

FIG. 3a schematically illustrates a semiconductor device 300 comprising a first transistor 350A and a second transistor 350B, which may have substantially the same configuration as described with reference to the devices 100 and 200. Respective components may be indicated by the same reference numerals except for the first digit which is a “3” compared to a “1” or “2” for the devices 100 and 200. Hence, a respective description of these similar components will be omitted.

In one illustrative embodiment, the gate electrode 353 of the transistors 350A, 350B may comprise a cap layer 308, which may be comprised of silicon nitride and the like, and which may be formed, for instance, during the patterning of the gate electrode 353. Consequently, the spacer structure 355 may be formed on the basis of the combined heights of the gate electrode 353 including the cap layer 308. In other illustrative embodiments, the cap layer 308 may be omitted and the gate electrode 353 may be formed with a certain amount of excess height to compensate for a respective material loss in a subsequent manufacturing stage, as will be explained with reference to FIG. 3b.

Moreover, the device 300 of FIG. 3a may comprise a sacrificial layer 310, which may be provided in a highly non-conformal manner so as to enclose the transistors 350A, 350B. For instance, the sacrificial layer 310 may be provided in the form of a polymer material that may be deposited by spin-on techniques in a highly non-conformal fashion. After application of the sacrificial layer 310, the material thereof may be treated in any appropriate manner, for instance by heat, radiation and the like, to cure the material and to thereby impart enhanced mechanical stability to the layer 310.

FIG. 3b schematically illustrates the semiconductor device 300 during a removal process 312 which may comprise a chemical mechanical polishing (CMP) process during which material of the sacrificial layer 310 may increasingly be removed, thereby exposing the cap layer 308 and the spacer structure 355, wherein, in the further process, the cap layer 308 and an upper portion 355U of the spacer structure 355 may be removed, while the residue of the sacrificial layer 310 may provide mechanical integrity of the device 300. Consequently, an upper surface 355S of the inner spacer element 355B may be exposed in a highly controllable manner and with high uniformity across the entire substrate 301. Thereafter the remaining sacrificial layer 310 may be removed by any appropriate selective etch process on the basis of well-established recipes, or by other techniques, such as heat treatment and the like, thereby also exposing the outer spacer element 355C. Next, the further processing may be continued on the basis of a highly selective etch process for removing the outer spacer 355C and a portion of the inner spacer 355B in a common process, as is previously described with respect to the etch process 213.

Consequently, also in this case, a high degree of process uniformity may be obtained during the reduction of the initial spacer structure 355, thereby providing advantages as previously described with reference to the device 200.

As a result, the present disclosure provides semiconductor devices including one or more transistor elements having a sophisticated dopant profile in the drain and source regions formed on the basis of a multiple spacer structure, the lateral size of which and the height thereof may be efficiently removed prior to forming metal silicide regions, thereby also exposing sidewall portions of the gate electrode. Hence, the increased amount of metal silicide in the gate electrode, as well as in the drain and source regions, provides enhanced conductivity of these components, while also highly stressed dielectric material may be positioned closer to the respective channel regions. This may be accomplished by exposing an upper portion or surface of an inner spacer element by using a sacrificial material layer, which may then be removed by an etch process and/or a CMP process in a highly controllable manner. Thereafter, the outermost spacer material of the inner spacer may be removed in a common etch process, wherein the reduced etch rate of the inner spacer provides high controllability, thereby allowing an efficient adjustment of the degree of exposure of the gate sidewalls.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a transistor element comprising a gate electrode structure having formed on sidewalls thereof a spacer structure including at least a first spacer element and a second spacer element comprised of substantially the same material, said first spacer element formed laterally between said gate electrode structure and said second spacer element, said spacer structure comprising a liner material separating said first and second spacer elements;
removing an upper portion of said first and second spacer elements and said liner material in a common removal process to expose a top portion of said first spacer element;
removing said second spacer element and material of said first spacer element in a selective etch process to form a reduced first spacer element; and
forming metal silicide regions in said gate electrode structure and drain and source regions of said transistor on the basis of said reduced first spacer element.

2. The method of claim 1, further comprising forming a sacrificial material layer on said spacer structure and removing said sacrificial material layer and said upper portion during said common removal process.

3. The method of claim 2, wherein said sacrificial material layer is comprised of silicon dioxide and said common removal process comprises performing a plasma assisted etch process designed to remove silicon dioxide.

4. The method of claim 1, wherein forming metal silicide regions comprises performing an etch process configured to remove residues of said liner material and to expose a portion of said gate electrode structure.

5. The method of claim 1, wherein forming said transistor element comprises forming an offset spacer element adjacent to sidewalls of said gate electrode structure prior to forming said first and second spacer elements of said spacer structure.

6. The method of claim 1, further comprising forming a dielectric material above said transistor element, said dielectric material having a high intrinsic stress to induce a strain in a channel region of said transistor element.

7. The method of claim 1, wherein said first and second spacer elements are comprised of a nitrogen-containing material and said liner material comprises silicon dioxide.

8. The method of claim 1, wherein said first and second spacer elements are comprised of a silicon dioxide and said liner material comprises a nitrogen-containing material.

9. The method of claim 2, wherein said sacrificial material layer is comprised of a silicon and nitrogen-containing material and said common removal process comprises performing a plasma assisted etch process designed to remove said silicon and nitrogen-containing material.

10. The method of claim 1, wherein removing an upper portion of said first and second spacer elements comprises performing a polishing process.

11. The method of claim 10, further comprising forming a sacrificial material in a non-conformal manner to cover said gate electrode structure prior to performing said polishing process.

12. The method of claim 10, further comprising forming a cap layer above said gate electrode structure prior to forming said first and second spacer elements.

13. A method, comprising:
forming a first spacer element laterally adjacent to a gate electrode of a transistor;
forming a liner material on said first spacer element;
forming a second spacer element on said liner material;
forming a sacrificial material layer above said gate electrode and said first and second spacer elements;
removing said sacrificial material layer by performing a first etch process to expose said second spacer element and a portion of said first spacer element; and
removing said second spacer element and a part of said first spacer element in a common second etch process.

14. The method of claim 13, wherein performing said first etch process comprises establishing a plasma ambient designed to remove material of said sacrificial layer.

15. The method of claim 13, wherein said sacrificial layer comprises silicon dioxide.

16. The method of claim 15, wherein forming said liner material comprises depositing a silicon dioxide material.

17. The method of claim 13, further comprising controlling said second etch process to adjust a residual size of said first spacer element.

18. The method of claim 13, further comprising performing a cleaning process to remove residues of said liner material and to expose portions of sidewalls of said gate electrode and forming metal silicide in said exposed sidewall portions using a residue of said first spacer element as a mask.

19. A semiconductor device, comprising
a first transistor comprising:
a gate electrode and a spacer element formed laterally adjacent to said gate electrode to expose a portion of sidewalls of said gate electrode;
drain and source regions and a channel region formed in a semiconductor material;
metal silicide formed in said drain and source regions and a top surface and said exposed portion of said gate electrode;
a first etch stop layer having an intrinsic stress level designed to induce a first type of strain in said channel region for enhancing charge carrier mobility; and
an interlayer dielectric material formed above said first etch stop layer.

20. The semiconductor device of claim 19, wherein a dopant profile of said drain and source regions has a shallow portion extending laterally outwards from said spacer element.

21. The semiconductor device of claim 20, further comprising a second transistor comprising:
a gate electrode and a spacer element formed laterally adjacent to said gate electrode to expose a portion of sidewalls of said gate electrode;
drain and source regions and a channel region formed in said semiconductor material;
metal silicide formed in said drain and source regions and a top surface and said exposed portion of said gate electrode of the second transistor; and
a second etch stop layer having an intrinsic stress level designed to induce a second type of strain in said channel region of the second transistor for enhancing charge carrier mobility, said second type of strain differing from said first type of strain.
